(19) United States
(12) Patent Application Publication
(10) Pub. No.: US 2021/0242097 A1
(43) Pub. Date: Aug. 5, 2021

(54) Method of Packaging an Integrated Circuit

(71) Applicant: Carbon, Inc., Redwood City, CA (US)

(72) Inventors: William C. HOLTON, Chapel Hill, NC (US); James Patrick TROISE, San Francisco, CA (US); Gurjeev CHADHA, Union City, CA (US); Joseph M. DESIMONE, Monte Sereno, CA (US)

(21) Appl. No.: 17/264,057

(22) PCT Filed: Jul. 31, 2019
(86) PCT No.: PCT/US2019/044357

§ 371 Date: Jan. 28, 2021

Related U.S. Application Data
(60) Provisional application No. 62/713,730, filed on Aug. 2, 2018.

(51) Int. Cl. H01L 23/053; H01L 23/08; H01L 23/00; H01L 21/52; H01L 23/373; B33Y 80/00

(52) U.S. Cl. CPC H01L 23/053; H01L 23/08; H01L 24/14; H01L 21/52; B29C 64/124; H01L 23/3737; B33Y 80/00; H01L 2224/14131; H01L 2224/11013; H01L 24/11

(57) ABSTRACT

A method of packaging an integrated circuit includes (a) providing: (i) an integrated circuit (e.g., in wafer form) having a two-dimensional contact array on a top surface thereof, (ii) a polymer shell lower portion, and (iii) a polymer shell upper portion, said upper portion having a two-dimensional array of openings formed therein, which array of openings corresponds to said two dimensional contact array; wherein one or both of said polymer shell upper and lower portions are produced by the process of additive manufacturing; and (b) enclosing said integrated circuit between said polymer shell lower portion and said polymer shell upper portion with said contact array aligned with array of openings to produce a integrated circuit packaged within a polymer shell.

### FIELD OF THE INVENTION

The present invention concerns additive manufacturing, and particularly concerns the use of additive manufacturing in the packaging of integrated circuits.

### BACKGROUND OF THE INVENTION

Packaging of integrated circuits (ICs) has long been a back-end operation. For example, completed and tested wafers were typically produced in one location and shipped to another for packaging, initially in dual inline plastic packages (DIPs) where the wafer was thinned, backside metallized, diced into individual ICs, cemented to a metal lead frame, ABACUS gold wire bonded from the chip bond pads (typically at the chip edge to the lead frame), and sealed in a plastic package. These back-end steps are labor-intensive and typically done in a low-cost labor region, from which the product was exported.

With progress down the Gordon Moore learning curve (“Moore's law”) to a much greater number of ICs per chip at much smaller feature size and higher speed of operation, the variety of different package options for ICs has proliferated. Issues of power dissipation and desire for lower inductance became increasingly important, and a need for new approaches to packaging of ICs, with greater package design flexibility, has emerged.

### SUMMARY

The present invention transitions IC packaging technology to incorporate the packaging as the final front-end process to provide, for example, an IC package of superior heat removal and/or lower inductance for high performance packages. For example, a pin grid array flip chip technology that does not incorporate a lead frame to transition output pads from the chip to the output connectors. The final IC product would be completed as the last stage of the front-end process.

To prepare the chip for packaging, a final oxide and patterned metal layer to reposition the bonding pads to the top surface of the chip in an array can be added as a last step to front-end manufacturing. Alternately, a redesign would eliminate the edge bonding pads, placing them on the top surface in the array.

The package front consisting of a shallow plastic dish structure would be produced first, by additive manufacturing, and the IC chip cemented on the bottom surface of the dish interior. The structure of the dish could be fabricated to contain or secure a metal plate on the outer top surface for heat distribution (or other heat dissipation features) and the polymer resin from which the package is produced could contain thermally conductive particles, such as metal particles, to increase its thermal conductivity.

The IC chip contained in the package top is then placed in an additive manufacturing apparatus, and the bottom package cover fabricated with conical thru holes aligned to the array of bonding pads on the top surface of the IC chip Finally, metal is deposited to connect the IC chip pads to a fabricated bump on the top package surface. The use of a lead frame and gold wire ABACUS bonding is eliminated, resulting in decreased inductance in the package. Alignment of the chip to the image projected by the apparatus constructing the resulting package can be addressed by image analysis using longer wavelength and software control, before package formation begins.

In some embodiments, a method of packaging an integrated circuit comprises (a) providing: (i) an integrated circuit (e.g., in wafer form) having a two-dimensional contact array on a top surface thereof, (ii) a polymer shell lower portion, and (iii) a polymer shell upper portion, said upper portion having a two-dimensional array of openings formed therein. The array of openings corresponds to the two dimensional contact array; and one or both of said polymer shell upper and lower portions are produced by the process of additive manufacturing. The method further includes the step of (b) enclosing the integrated circuit between the polymer shell lower portion and the polymer shell upper portion with the contact array aligned with array of openings to produce a integrated circuit packaged within a polymer shell.

In some embodiments, the method further includes a step of (c) filling the openings with a conductor (e.g., a metal conductor) to produce an external contact array (e.g., a bump pad) on the surface of the polymer shell corresponding to and in electrical contact with the two-dimensional contact array.

In some embodiments, the integrated circuit is provided without a lead frame, and is enclosed in said polymer shell without a lead frame.

In some embodiments, one or both of said polymer shell upper and lower portions includes at least one heat dissipation feature (e.g., heat exchange elements such as fins, including branched fins, cooling fluid channels including branched fluid channels, etc., including combinations thereof).

In some embodiments, the polymer shell upper and lower portions both include cooperating interlocking alignment features thereon (e.g., tongue and groove; post and recess, etc.).

In some embodiments, the process of additive manufacturing comprises a bottom-up or top-down stereolithography process (e.g., continuous liquid interface production, or “CLIP”).

In some embodiments, one or both of the polymer shell upper and lower portions are produced from a dual cure resin (e.g., an epoxy dual cure resin), optionally in a green state (photopolymerized, but not further cured).

In some embodiments, the packaged integrated circuit is baked to further cure the polymer shell.

In some embodiments, the encapsulated object comprises multiple interconnected devices (e.g., two integrated circuits directly connected to one another, such as: wafer-level dies packaged together; multiple stacks of dies packaged together; wafer-level dies packaged with other MEMS or optoelectronics; finished dies with MEMS or optoelectronics packaged together; GPU/CPU chips with memory die packaged together (optionally but preferably combined with cooling channels etc. in the polymer shell); multiple NAND die with controller packaged together (optionally but preferably combined with cooling channels etc. in the polymer shell), etc.).

In some embodiments, a product is produced by the process described above.

In some embodiment, a packaged integrated circuit product includes: (a) an integrated circuit (e.g., in wafer form) having a two-dimensional contact array on a top surface thereof, (b) a polymer shell lower portion, and (c) a polymer shell upper portion connected to the polymer shell lower portion with said integrated circuit enclosed therein, the upper portion having a two-dimensional array of openings formed therein. The array of openings corresponds to said two-dimensional contact array. One or both of the polymer shell upper and lower portions are produced by the process of additive manufacturing. The product optionally but preferably includes (d) a conductor (e.g., a metal conductor) filing the openings and providing an external contact array (e.g., a bump pad) on the surface of the polymer shell corresponding to and electrically connected to said two-dimensional contact array.

In some embodiments, the integrated circuit is enclosed in the polymer shell without a lead frame.

In some embodiments, one or both of the polymer shell upper and lower portions includes at least one heat dissipation feature (e.g., heat exchange elements such as fins, including branched fins, cooling fluid channels including branched fluid channels, etc., including combinations thereof).

In some embodiments, the polymer shell upper and lower portions both include cooperating interlocking alignment features thereon (e.g., tongue and groove; post and recess, etc.).

In some embodiments, the process of additive manufacturing comprises a bottom-up or top-down stereolithography process (e.g., continuous liquid interface production, or “CLIP”).

In some embodiments, one or both of the polymer shell upper and lower portions are produced from a dual cure resin (e.g., an epoxy dual cure resin).

In some embodiments, the encapsulated integrated circuit comprises multiple interconnected devices (e.g., two integrated circuits, preferably directly connected to one another, such as: wafer-level dies packaged together; multiple stacks of dies packaged together; wafer-level dies packaged with other MEMS or optoelectronics; finished dies with MEMS or optoelectronics packaged together; GPU/CPU chips with memory die packaged together (optionally but preferably combined with cooling channels etc. in the polymer shell); multiple NAND die with controller packaged together (optionally but preferably combined with cooling channels etc. in the polymer shell), etc.).

The foregoing and other objects and aspects of the present invention are explained in greater detail in the drawings herein and the specification set forth below. The disclosures of all United States patent references cited herein are to be incorporated herein by reference.

### BRIEF DESCRIPTION OF THE DRAWINGS

FIG. 1 schematically illustrates a non-limiting example of a process of the present invention.

### DETAILED DESCRIPTION OF ILLUSTRATIVE EMBODIMENTS

The present invention is now described more fully hereinafter with reference to the accompanying drawings, in which embodiments of the invention are shown. This invention may, however, be embodied in many different forms and should not be construed as limited to the embodiments set forth herein; rather these embodiments are provided so that this disclosure will be thorough and complete and will fully convey the scope of the invention to those skilled in the art.

As used herein, the term “and/or” includes any and all possible combinations of one or more of the associated listed items, as well as the lack of combinations when interpreted in the alternative (“or”).

1. Polymerizable Liquids (Resins).

Resins.

Conventional (or “single cure”) resins, or dual cure resins, can be used to carry out the invention.

Dual cure additive manufacturing resins are described in, for example, Rolland et al., U.S. Pat. Nos. 9,676,963; 9,598,606; and 9,453,142, and in Wu et al., US Patent Application Pub. No. US2017/0260418, the disclosures of which are incorporated herein by reference. Constituents of such resins may be used with the prepolymers of the present invention, or the prepolymers of the present invention may be added to such resins, as described further above and below.

Example dual cure resins include, but are not limited to, Carbon Inc. EPU 40, EPU 41, FPU, RPU 70, SIL 30, and EPX 82 resins, all available from Carbon Inc. 1089 Mills Way, Redwood City, Calif. 94063 USA.

Additive Manufacturing.

The resins may be used to make three-dimensional objects, in a “light” cure (typically by additive manufacturing) which in some embodiments generates a “green” intermediate object, followed in some embodiments by a second (typically heat) cure of that intermediate object.

Techniques for additive manufacturing are known. Suitable techniques include bottom-up or top-down additive manufacturing, generally known as stereolithography. Such methods are known and described in, for example, U.S. Pat. No. 5,236,637 to Hull, U.S. Pat. Nos. 5,391,072 and 5,529,473 to Lawton, U.S. Pat. No. 7,438,846 to John, U.S. Pat. No. 7,892,474 to Shkolnik, U.S. Pat. No. 8,110,135 to El-Siblani, U.S. Patent Application Publication No. 2013/0292862 to Joyce, and US Patent Application Publication No. 2013/0295212 to Chen et al. The disclosures of these patents and applications are incorporated by reference herein in their entirety.

In some embodiments, the intermediate object is formed by continuous liquid interface production (CLIP). CLIP is known and described in, for example, PCT Application Nos. PCT/US2014/015486 (published as U.S. Pat. No. 9,211,678 on Dec. 15, 2015); PCT/US2014/015506 (also published as U.S. Pat. No. 9,205,601 on Dec. 8, 2015), PCT/US2014/015497 (also published as U.S. Pat. No. 9,216,546 on Dec. 22, 2015), and in J. Tumbleston, D. Shirvanyants, N. Ermoshkin et al., Continuous liquid interface production of 3D Objects, Science 347, 1349-1352 (published online 16 Mar. 2015). See also R. Janusziewcz et al., Layerless fabrication with continuous liquid interface production, Proc. Natl. Acad Sci. USA 113, 11703-11708 (Oct. 18, 2016). In some embodiments, CLIP employs features of a bottom-up three-dimensional fabrication as described above, but the irradiating and/or said advancing steps are carried out while also concurrently maintaining a stable or persistent liquid interface between the growing object and the build surface or window, such as by: (i) continuously maintaining a dead zone of polymerizable liquid in contact with said build surface, and (ii) continuously maintaining a gradient of polymerization zone (such as an active surface) between the dead zone and the solid polymer and in contact with each thereof, the gradient of polymerization zone comprising the first component in partially cured form. In some embodiments of CLIP, the optically transparent member comprises a semipermeable member (e.g., a fluoropolymer), and the continuously maintaining a dead zone is carried out by feeding an inhibitor of polymerization through the optically transparent member, thereby creating a gradient of inhibitor in the dead zone and optionally in at least a portion of the gradient of polymerization zone. Other approaches for carrying out CLIP that can be used in the present invention and potentially obviate the need for a semipermeable “window” or window structure include utilizing a liquid interface comprising an immiscible liquid (see L. Robeson et al., WO 2015/164234, published Oct. 29, 2015), generating oxygen as an inhibitor by electrolysis (see I Craven et al., WO 2016/133759, published Aug. 25, 2016), and incorporating magnetically positionable particles to which the photoactivator is coupled into the polymerizable liquid (see J. Rolland, WO 2016/145182, published Sep. 15, 2016).

After the intermediate three-dimensional object is formed, it is optionally cleaned, optionally dried (e.g., air dried) and/or rinsed (in any sequence). It is then further cured, preferably by heating (although further curing may in some embodiments be concurrent with the first cure, or may be by different mechanisms such as contacting to water, as described in U.S. Pat. No. 9,453,142 to Rolland et al.).

2. Cleaning or Washing.

Objects as described above can be cleaned in any suitable apparatus, in some embodiments with a wash liquid as described above and below, and in other embodiments by wiping (with an absorbent, air blade, etc.) spinning, or variations thereof.

Wash liquids that may be used to carry out the present invention include, but are not limited to, water, organic solvents, and combinations thereof (e.g., combined as co-solvents), optionally containing additional ingredients such as surfactants, chelants (ligands), enzymes, borax, dyes or colorants, fragrances, etc., including combinations thereof. The wash liquid may be in any suitable form, such as a solution, emulsion, dispersion, etc.

In some preferred embodiments, where the residual resin has a boiling point of at least 90 or 100° C. (e.g., up to 250 or 300° C., or more), the wash liquid has a boiling point of at least 30° C., but not more than 80 or 90° C. Boiling points are given herein for a pressure of 1 bar or 1 atmosphere.

In some embodiments, the wash liquid consists of a 50:50 (volume:volume) solution of water and an alcohol organic solvent such as isopropanol (2-propanol).

Examples of hydrofluorocarbon solvents that may be used to carry out the present invention include, but are not limited to, 1,1,1,2,3,4,4,5,5,5-decafluoropentane (Vertrel® XF, DuPont™ Chemours), 1,1,1,3,3-Pentafluoropropane, 1,1,1,3,3-Pentafluorobutane, etc.

Examples of hydrochlorofluorocarbon solvents that may be used to carry out the present invention include, but are not limited to, 3,3-Dichloro-1,1,1,2,2-pentafluoropropane, 1,3-Dichloro-1,1,2,2,3-pentafluoropropane, 1,1-Dichloro-1-fluoroethane, etc., including mixtures thereof.

Examples of hydrofluoroether solvents that may be used to carry out the present invention include, but are not limited to, methyl nonafluorobutyl ether (HFE-7100), methyl nonafluoroisobutyl ether (HFE-7100), ethyl nonafluorobutyl ether (HFE-7200), ethyl nonafluoroisobutyl ether (HFE-7200), 1,1,2,2-tetrafluoroethyl-2,2,2-trifluoroethyl ether, etc., including mixtures thereof. Commercially available examples of this solvent include Novec 7100 (3M), Novec 7200 (3M).

Examples of volatile methylsiloxane solvents that may be used to carry out the present invention include, but are not limited to, hexamethyldisiloxane (OS-10, Dow Corning), octamethyltrisiloxane (OS-20, Dow Corning), decamethyltetrasiloxane (OS-30, Dow Corning), etc., including mixtures thereof.

Other siloxane solvents (e.g., NAVSOLVE™ solvent) that may be used to carry out the present invention include but are not limited to those set forth in U.S. Pat. No. 7,897,558.

In some embodiments, the wash liquid comprises an azeotropic mixture comprising, consisting of, or consisting essentially of a first organic solvent (e.g., a hydrofluorocarbon solvent, a hydrochlorofluorocarbon solvent, a hydrofluoroether solvent, a methylsiloxane solvent, or a combination thereof; e.g., in an amount of from 80 or 85 to 99 percent by weight) and a second organic solvent (e.g., a C1-C4 or C6 alcohol such as methanol, ethanol, isopropanol, Cert-butanol, etc.; e.g., in an amount of from 1 to 15 or 20 percent by weight). Additional ingredients such as surfactants or chelants may optionally be included. In some embodiments, the azeotropic wash liquid may provide superior cleaning properties, and/or enhanced recyclability, of the wash liquid. Additional examples of suitable azeotropic wash liquids include, but are not limited to, those set forth in U.S. Pat. Nos. 6,008,179; 6,426,327; 6,753,304; 6,288,018; 6,646,020; 6,699,829; 5,824,634; 5,196,137; 6,689,734; and 5,773,403, the disclosures of which are incorporated by reference herein in their entirety.

When the wash liquid includes ingredients that are not desired for carrying into the further curing step, in some embodiments the initial wash with the wash liquid can be followed with a further rinsing step with a rinse liquid, such as water (e.g., distilled and/or deionized water), or a mixture of water and an alcohol such as isopropanol.

3. Further Curing.

After washing, the object is in some embodiments further cured, preferably by heating or baking.

Heating may be active heating (e.g., in an oven, such as an electric, gas, solar oven or microwave oven, heated bath, or combination thereof), or passive heating (e.g., at ambient (room) temperature). Active heating will generally be more rapid than passive heating and in some embodiments is preferred, but passive heating—such as simply maintaining the intermediate at ambient temperature for a sufficient time to effect further cure—is in some embodiments preferred.

In some embodiments, the heating step is carried out at at least a first (oven) temperature and a second (oven) temperature, with the first temperature greater than ambient temperature, the second temperature greater than the first temperature, and the second temperature less than 300° C. (e.g., with ramped or step-wise increases between ambient temperature and the first temperature, and/or between the first temperature and the second temperature). In some embodiments, the heating step is carried out at at least a first (oven) temperature and a second (oven) temperature, with the first temperature greater than ambient temperature, the second temperature greater than the first temperature, and the second temperature less than 300° C. (e.g., with ramped or step-wise increases between ambient temperature and the first temperature, and/or between the first temperature and the second temperature).

For example, the intermediate may be heated in a stepwise manner at a first temperature of about 70° C. to about 150° C., and then at a second temperature of about 150° C. to 200 or 250° C., with the duration of each heating depending on the size, shape, and/or thickness of the intermediate. In another embodiment, the intermediate may be cured by a ramped heating schedule, with the temperature ramped from ambient temperature through a temperature of 70 to 150° C., and up to a final (oven) temperature of 250 or 300° C., at a change in heating rate of 0.5° C. per minute, to 5° C. per minute. (See, e.g., U.S. Pat. No. 4,785,075).

In some embodiments, the heating step is carried out in an inert gas atmosphere. Inert atmosphere ovens are known, and generally employ an atmosphere enriched in nitrogen, argon, or carbon dioxide in the oven chamber. Suitable examples include but are not limited to those available from Grieve Corporation, 500 Hart Road Round Lake, Ill. 60073-2898 USA, Davron Technologies, 4563 Pinnacle Lane, Chattanooga, Tenn. 37415 USA, Despatch Thermal Processing Technology, 8860 207th Street, Minneapolis, Minn. 55044 USA, and others.

In other embodiments, the heating step is carried out in an inert liquid bath. Suitable inert liquids may be aqueous liquids (i.e., pure water, salt solutions, etc.), organic liquids (e.g., mineral oil, fluorinated, perfluorinated, and polysiloxane organic compounds such as perfluorohexane, perfluoro(2-butyl-tetrahydrofurane), perfluorotripentylamine, etc. (commercially available as PERFLUORINERT® inert liquids from 3M Company), and mixtures thereof. These inert liquids can be deoxygenated if necessary, such as by bubbling an inert gas such as nitrogen through the liquid, by boiling the inert liquid, by mixing oxygen-scavenging agents with the inert liquid medium (or contacting them to one another), etc., including combinations thereof (see, e.g., U.S. Pat. No. 5,506,007).

In some embodiments, the further curing or heating step (whether carried out in a liquid or gas fluid) is carried out at an elevated pressure (e.g., elevated sufficiently to reduce volatilization or out-gassing of residual monomers, prepolymers, chain extenders, and/or reactive diluents, etc.). Suitable pressure ranges are from 10 or 15 psi to 70 or 100 psi, or more.

In some embodiments, objects formed by additive manufacturing as described above may include polymer shells or portions thereof as described in the following non-limiting example embodiments. Such polymer shells may be used to encapsulate an object or assembly of objects.

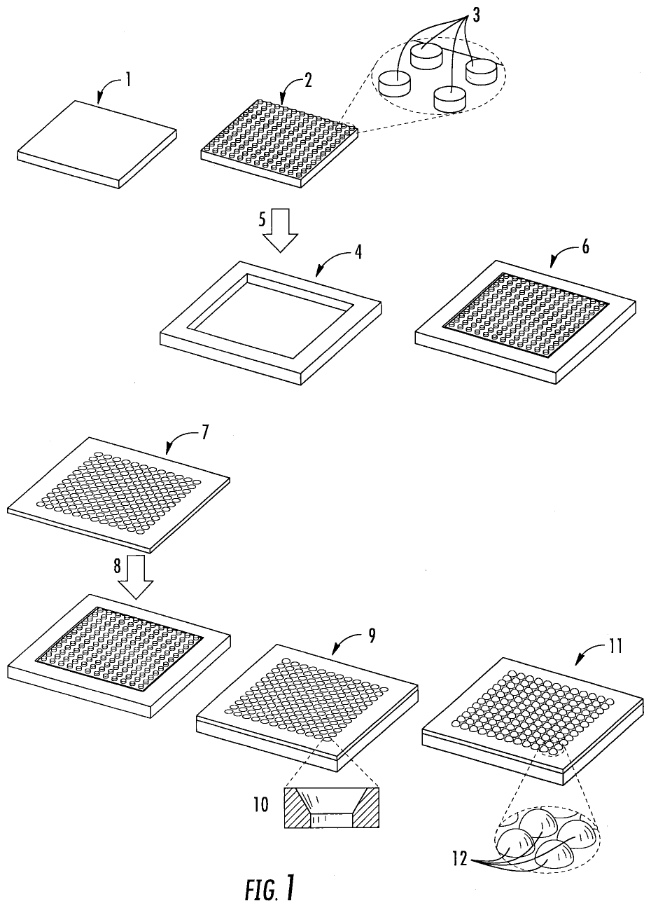

A non-limiting example of a process of the invention is schematically illustrated in FIG. 1, where integrated circuit (IC, chip) 1 is without repositioned bonding pads, and chip 2 is a chip with a repositioned bonding pad arrays (3 in detail view) on a wide (e.g., top or bottom), rather than edge, surface thereof. A polymer shell lower portion 4 is produced, preferably by additive manufacturing as described above (in the green state, or optionally further cured such as by baking), and the chip 2 placed therein (step 5) to produce an intermediate object 6. Note that the lower portion preferably has a recess formed therein that corresponds to the shape of the object (or assembly of objects as discussed below) to be inserted therein.

Next, a polymer shell upper portion 7 is produced, preferably by additive manufacturing as described above (in the green state, or optionally further cured such as by baking) with through holes (e.g. conical through-holes 10) that align with the bonding pad array. The upper portion is aligned with and secured to the lower portion to produce (step 8) an encapsulated object 9 comprising the upper portion, the lower portion, and the chip (or assembly of objects). A conductor such as metal (e.g., copper, solder) or a conductive-polymer is then deposited in the through-holes, leaving external contact elements or “bumps,” to produce the packaged object 12 with a bump array (or in the case of a conductive polymer, a “plastic ball grid array” or “PBGA”).

In some embodiments, the polymer shell upper and/or lower portions can comprise a plurality of heat exchange elements formed thereon (not shown), optionally in a branched configuration (e.g., a fractal branching pattern). Examples of such branched heat exchange elements include but are not limited to those set forth in U.S. Pat. No. 6,688,381 to Pence and U.S. Pat. No. 9,228,785 to Poltorak, and in US Patent Application Publication No. 2009/0050293 to Kuo, the disclosures of which are incorporated herein by reference (note that while, in some embodiments described in the foregoing references multiple pieces are assembled, in the present invention the branched heat exchange elements may be comprised of a single unitary part (e.g., formed by additive manufacturing as described herein). Also, the heat exchange elements may comprise the surface portions of interconnected voids formed in the shell upper and/or lower portions, providing a regular or irregular open-cell foam (e.g., a Menger sponge) on the package (although preferably retaining a continuous, closed layer on inner surface portions of the shell, so that the packaged chip is sealed from fluid communication with the exterior surface of the shell).

In addition, in some embodiments, the polymer shell upper and/or lower portions can contain a plurality of fluid passages therein, optionally in a branched configuration (e.g., a fractal or arborized branching patterns), for containing and optionally circulating a cooling fluid. Examples are shown in U.S. Pat. No. 8,037,927 to Schuette and U.S. Pat. No. 6,843,308 to Duval.

In some embodiments, multiple interconnected chips, microelectronic systems, optoelectronic devices, MEMS devices, or combinations thereof are packaged in the same encapsulating polymer shell, to allow for shortened interconnect paths between those multiple devices. The shortened interconnects enabled by the present invention aid in reducing inductances and result in better I/O performance.

Note also that, while in some embodiments the objects, polymer shell upper portion, and/or polymer shell lower portion, can be secured to one another with an adhesive, in other embodiments, by forming the shell upper and/or lower portions from a dual cure resin, some or all of the parts may be assembled with the polymer shell portion(s) in a green state, and adhesion accomplished by further curing the assembled object so that during further curing they adhere together, such as described in J. Rolland et al., Fabrication of compound products from multiple intermediates by additive manufacturing with dual cure resins, PCT Application Publication No. WO 2017/112682 (published Jun. 29, 2017).

The foregoing is illustrative of the present invention, and is not to be construed as limiting thereof. The invention is defined by the following claims, with equivalents of the claims to be included therein.

1. A method of packaging an integrated circuit, comprising the steps of:
(a) providing: (i) an integrated circuit having a two-dimensional contact array on a top surface thereof, (ii) a polymer shell lower portion, and (iii) a polymer shell upper portion, said upper portion having a two-dimensional array of openings formed therein, which array of openings corresponds to said two dimensional contact array;
wherein one or both of said polymer shell upper and lower portions are produced by the process of additive manufacturing; and
(b) enclosing said integrated circuit between said polymer shell lower portion and said polymer shell upper portion with said contact array aligned with array of openings to produce a integrated circuit packaged within a polymer shell.

2. The method of claim 1, further comprising:
(c) filling said openings with a conductor to produce an external contact array on the surface of said polymer shell corresponding to and in electrical contact with said two-dimensional contact array.

3. The method of claim 1, wherein said integrated circuit is provided without a lead frame, and is enclosed in said polymer shell without a lead frame.

4. The method of claim 1, wherein one or both of said polymer shell upper and lower portions includes at least one heat dissipation feature.

5. The method of claim 1, wherein said polymer shell upper and lower portions both include cooperating interlocking alignment features thereon.

6. The method of claim 1, wherein said process of additive manufacturing comprises a bottom-up or top-down stereolithography process (e.g., continuous liquid interface production, or “CLIP”).

7. The method of claim 1, wherein one or both of said polymer shell upper and lower portions are produced from a dual cure resin.

8. The method of claim 1, wherein said packaged integrated circuit is baked to further cure said polymer shell.

9. The method of claim 1, wherein said encapsulated object comprises multiple interconnected devices.

10. A product produced by a process comprising:
(a) providing: (i) an integrated circuit having a two-dimensional contact array on a top surface thereof, (ii) a polymer shell lower portion, and (iii) a polymer shell upper portion, said upper portion having a two-dimensional array of openings formed therein, which array of openings corresponds to said two dimensional contact array,
wherein one or both of said polymer shell upper and lower portions are produced by the process of additive manufacturing, and
(b) enclosing said integrated circuit between said polymer shell lower portion and said polymer shell upper portion with said contact array aligned with array of openings to produce a integrated circuit packaged within a polymer shell.

11. A packaged integrated circuit product, comprising:
(a) an integrated circuit having a two-dimensional contact array on a top surface thereof,
(b) a polymer shell lower portion, and
(c) a polymer shell upper portion connected to said polymer shell lower portion with said integrated circuit enclosed therein, said upper portion having a two-dimensional array of openings formed therein, which array of openings corresponds to said two-dimensional contact array;
wherein one or both of said polymer shell upper and lower portions are produced by the process of additive manufacturing; and
(d) optionally but preferably a conductor filing said openings and providing an external contact array on the surface of said polymer shell corresponding to and electrically connected to said two-dimensional contact array.

12. The product of claim 11, wherein said integrated circuit is enclosed in said polymer shell without a lead frame.

13. The product of claim 11, wherein one or both of said polymer shell upper and lower portions includes at least one heat dissipation feature.

14. The product of claim 11, wherein said polymer shell upper and lower portions both include cooperating interlocking alignment features thereon.

15. The method of claim 11, wherein said process of additive manufacturing comprises a bottom-up or top-down stereolithography process.

16. The product of claim 11, wherein one or both of said polymer shell upper and lower portions are produced from a dual cure resin.

17. The product of claim 11, wherein said encapsulated integrated circuit comprises multiple interconnected devices.

18. The method of claim 7, wherein said dual cure resin comprises an epoxy dual cure resin in a green state that is photopolymerized, but not further cured.

19. The method of claim 9, wherein said multiple interconnected devices comprise two integrated circuits directly connected to one another, said two integrated circuits comprising wafer-level dies packaged together; multiple stacks of dies packaged together; wafer-level dies packaged with other MEMS or optoelectronics; finished dies with MEMS or optoelectronics packaged together; GPU/CPU chips with memory die packaged together (optionally combined with cooling channels etc. in the polymer shell); or multiple NAND die with controller packaged together (optionally combined with cooling channels etc. in the polymer shell)).

20. The product of claim 11, wherein said multiple interconnected devices comprise two integrated circuits directly connected to one another, said two integrated circuits comprising wafer-level dies packaged together; multiple stacks of dies packaged together; wafer-level dies packaged with other MEMS or optoelectronics; finished dies with MEMS or optoelectronics packaged together; GPU/CPU chips with memory die packaged together (optionally combined with cooling channels etc. in the polymer shell); or multiple NAND die with controller packaged together (optionally combined with cooling channels etc. in the polymer shell)).
